(19) United States
(12) Patent Application Publication
(10) Pub. No.: US 2013/0264714 A1
(43) Pub. Date: Oct. 10, 2013

(54) SEMICONDUCTOR DEVICE AND METHOD OF ASSEMBLING SAME

(71) Applicants: Guo Liang Gong, Tianjin (CN); Shunan Qiu, Yingtan (CN); Xuesong Xu, Tianjin (CN)

(72) Inventors: Guo Liang Gong, Tianjin (CN); Shunan Qiu, Yingtan (CN); Xuesong Xu, Tianjin (CN)

(73) Assignee: FREESCALE SEMICONDUCTOR, INC, Austin, TX (US)

(21) Appl. No.: 13/607,731

(22) Filed: Sep. 9, 2012

(30) Foreign Application Priority Data
Apr. 10, 2012 (CN) 201210131114.0

(51) Int. Cl. H01L 23/48; H01L 21/58

(52) U.S. Cl. 257/773; 438/113; 257/E23.01; 257/E21.505

(57) ABSTRACT

A semiconductor die has interface electrodes on an interface surface and an electrically conductive layer on a mounting surface that is opposite to the interface surface. The electrically conductive layer extends onto side regions of the semiconductor die. Electrical conductors couple the interface electrodes to external connector pads. A solder alloy joins the semiconductor die to a flag. The solder alloy is disposed between the flag and the electrically conductive layer and provides a joint between the flag and both the mounting surface and the side regions.

### BACKGROUND OF THE INVENTION

The present invention relates to semiconductor device packaging, and, more particularly, to forming a reliable joint between a semiconductor die and a die attach pad to which it is mounted.

Semiconductor devices are typically formed by mounting a semiconductor die to either a lead frame or a substrate resembling a small circuit board. When a semiconductor die is packaged using a lead frame, the semiconductor die is mounted to a die attach pad, often called a flag. The flag usually is attached to an outer frame with tie bars. External connector pads on the lead frame, often called lead fingers, are electrically connected to electrodes of the die with bond wires to provide a means of easily electrically connecting the die to circuit boards and the like. After wire bonding, the semiconductor die and external connector pads are encapsulated with a material such as a plastics material to form a semiconductor device (i.e. a packaged die), leaving only the outer frame and some portion of the external connector pads exposed. The packaged semiconductor die is then cut (singulated) from the outer frame.

When a semiconductor die is packaged using a substrate that resembles a circuit board, the semiconductor die is mounted to a conductive mounting pad (or flag) located in a central region of the substrate. External connector pads on the substrate are wire bonded to pads or electrodes of the die and the semiconductor die and external connector pads are encapsulated to form a semiconductor device leaving only end portions or undersides of the external connector pads exposed.

When considering relatively high power semiconductor devices, there is a requirement for effective heat dissipation and a low resistance ground plane coupling between ground plane connections of the semiconductor die and an external connection of the package. This coupling is achieved by the underside of the die being coated with an electrically conductive layer that forms a ground plane of the die. The die is then mounted on a solder paste that has been deposited on the flag. The solder is then heated and when it solidifies it forms a solder joint affixing or joining the die to the flag. However, the solder joint may sometimes contain voids near a periphery of the conductive layer and the integrity of the solder joint is not always apparent by visual inspection. In addition, the conductivity and mechanical strength of the joint may not be adequate for certain applications especially when the semiconductor device has high power consumption.

### BRIEF DESCRIPTION OF THE DRAWINGS

The invention, together with objects and advantages thereof, may best be understood by reference to the following description of preferred embodiments together with the accompanying drawings in which:

FIG. 1 is a cross-sectional view of a conventional assembly including a semiconductor die placed on a solder paste covering a flag region of a substrate;

FIG. 2 is an enlarged cross sectional view of part of the conventional assembly of FIG. 1 after the solder paste has been heated to form a joint;

FIG. 3 is a plan view of part of silicon wafer comprising an array of semiconductor dies partially partitioned by milled channels in accordance with a first preferred embodiment of the present invention;

FIG. 4 is a cross sectional view through 4-4′ of FIG. 3;

FIG. 5 is a view of FIG. 4 after an electrically conductive layer has been deposited on a mounting surface of the semiconductor dies of FIG. 3 in accordance with a preferred embodiment of the present invention;

FIG. 6 is perspective view of a singulated semiconductor die of FIG. 5 in accordance with a preferred embodiment of the present invention;

FIG. 7 is an inverted view of a singulated semiconductor die of FIG. 5;

FIG. 8 is a view of a partial assembly of a semiconductor device including the singulated semiconductor die of FIG. 7 placed on a flag of a substrate in accordance with a preferred embodiment of the present invention;

FIG. 9 is a view of the partial assembly of FIG. 8 with a solder alloy joining the semiconductor die to the flag in accordance with a preferred embodiment of the present invention;

FIG. 10 is a view of the partial assembly of FIG. 9 with electrical conductors coupling the electrodes of the semiconductor die to respective external connector pads in accordance with a preferred embodiment of the present invention;

FIG. 11 is a cross-sectional view of a semiconductor device in accordance with a preferred embodiment of the present invention;

FIG. 12 is cross-sectional view of a partial assembly of a semiconductor device including the singulated semiconductor die of FIG. 7 joined by a solder alloy to a lead frame flag in accordance with another preferred embodiment of the present invention;

FIG. 13 is cross-sectional view a semiconductor device in accordance with a preferred embodiment of the present invention;

FIG. 14 is a cross-sectional view of part of a silicon wafer comprising an array of semiconductor dies partially partitioned by milled channels in accordance with a preferred embodiment of the present invention;

FIG. 15 is cross-sectional view of a singulated semiconductor die in accordance with a preferred embodiment of the present invention;

FIG. 16 is cross-sectional view a semiconductor device in accordance with a preferred embodiment of the present invention;

FIG. 17 is cross-sectional inverted view of a singulated semiconductor die in accordance with a preferred embodiment of the present invention;

FIG. 18 is cross-sectional view a semiconductor device in accordance with a preferred embodiment of the present invention; and

FIG. 19 is a flow chart illustrating a method for assembling a semiconductor device in accordance with a preferred embodiment of the present invention.

### DETAILED DESCRIPTION OF PREFERRED EMBODIMENTS

The detailed description set forth below in connection with the appended drawings is intended as a description of presently preferred embodiments of the invention, and is not intended to represent the only forms in which the present invention may be practised. It is to be understood that the same or equivalent functions may be accomplished by different embodiments that are intended to be encompassed within the spirit and scope of the invention. In the drawings, like numerals are used to indicate like elements throughout. Furthermore, terms “comprises,” “comprising,” or any other variation thereof, are intended to cover a non-exclusive inclusion, such that module, circuit, device components, structures and method steps that comprises a list of elements or steps does not include only those elements but may include other elements or steps not expressly listed or inherent to such module, circuit, device components or steps. An element or step proceeded by “comprises . . . a” does not, without more constraints, preclude the existence of additional identical elements or steps that comprises the element or step.

In one embodiment, the present invention provides for a semiconductor device comprising a mount with a flag and external connector pads. There is a semiconductor die having interface electrodes on an interface surface and an electrically conductive layer on a mounting surface that is opposite to the interface surface. The electrically conductive layer extends onto at least one side region of the semiconductor die and electrical conductors couple the interface electrodes to respective pads of the external connector pads. A solder alloy joins the semiconductor die to the flag, wherein the solder alloy is disposed between the flag and the electrically conductive layer and provides a joint between the flag and both the mounting surface and the side region.

In another embodiment the present invention provides for a semiconductor die comprising an interface surface with associated interface electrodes and a mounting surface that is opposite to the interface surface. There are side regions between the interface surface and mounting surface, and an electrically conductive layer is deposited on the mounting surface and at least one of the side regions.

In a further embodiment the present invention provides for a method for manufacturing a semiconductor device, the method comprising Forming channels in a first side of a semiconductor wafer to thereby partition semiconductor dies in an array of such dies. The method then performs depositing a continuous sheet of electrically conductive material on the first side of the semiconductor wafer, wherein the electrically conductive material forms a continuous film that completely covers the first side. There is then performed a process of singulating the semiconductor dies into individual dies. When singulated, each of the dies includes: an interface surface with associated interface electrodes, the interface being part of a second side of the semiconductor wafer that is opposite to the first side; a mounting surface formed from part of the first side of the semiconductor wafer; and side regions between the interface surface and mounting surface, wherein the electrically conductive layer covers the mounting surface and part of each side region. The method then performs a process of joining the semiconductor die to a flag of a mount, the joining is effected by a solder alloy disposed between the flag and the electrically conductive layer. The alloy provides a joint between the flag, the mounting surface and the side regions. Wire bonding is then performed to wire bond the interface electrodes to respective external connector pads of the mount. The semiconductor die is then encapsulated.

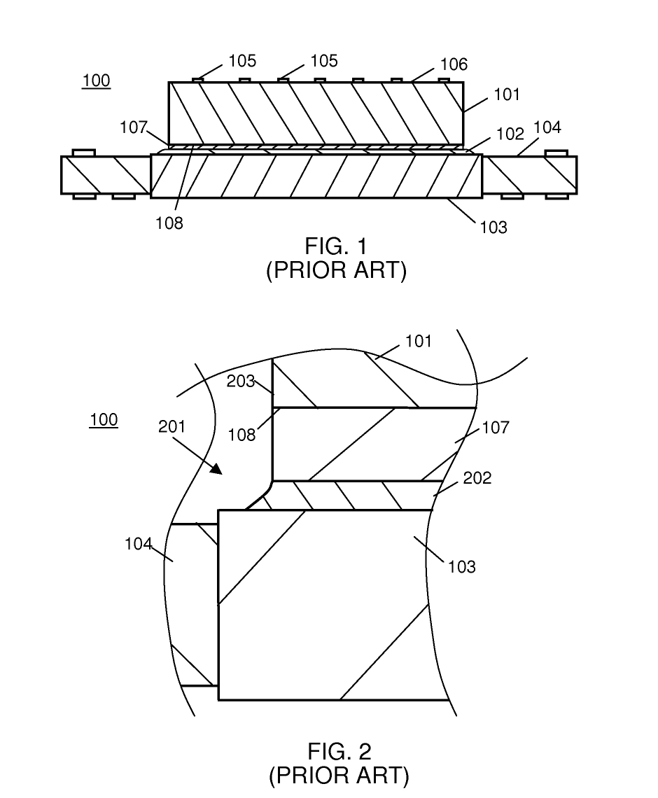

Referring to FIG. 1 there is illustrated a cross sectional view of a conventional assembly 100 including a semiconductor die 101 placed on a solder paste compound 102 covering a flag region 103 of a substrate 104. The semiconductor die 101 has interface electrodes 105 on an interface surface 106 and an electrically conductive layer 107 on a mounting surface 108 that is opposite to the interface surface.

Referring to FIG. 2 there is illustrated an enlarged cross sectional view of part of the prior art assembly 100 after the solder paste compound 102 has been heated (re-flowed) to form a joint 201. The joint includes a solder alloy 202 disposed between the flag region 103 and the electrically conductive layer 107 and the joint 201 is effectively between the flag region 103 and electrically conductive layer 107. There is no solder alloy 202 soldered to the side region 203 of the semiconductor die 101 as the silicon die 101 is not solder wettable (the thickness of the electrically conductive layer 107 is exaggerated in this illustration). As a result there may be voids in the solder alloy 202 near the periphery of the joint 201 and the joint integrity is not always apparent by visual inspection. Further, the conductivity and mechanical strength of the joint 201 could be improved if the solder alloy 202 is also soldered to the side region 203 of the semiconductor die 101.

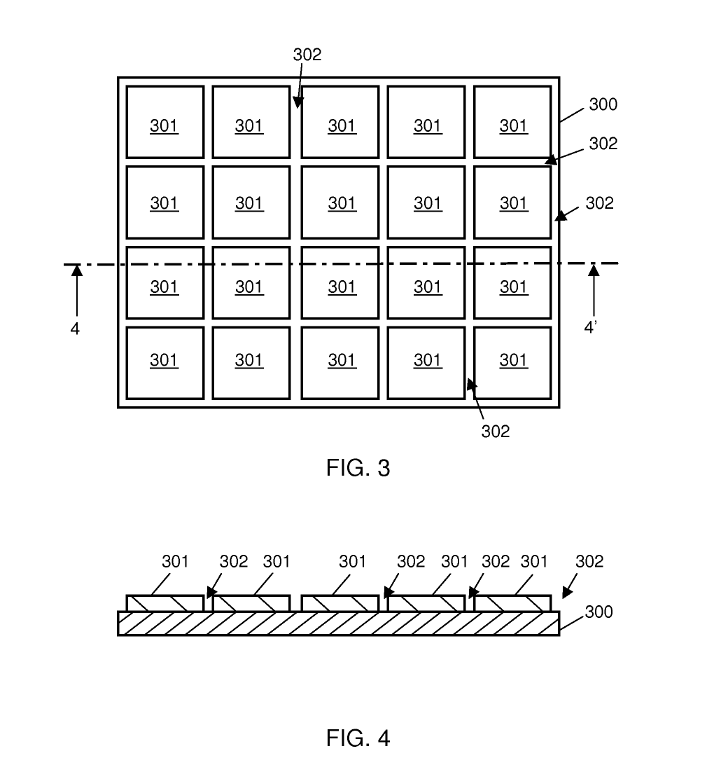

Referring to FIG. 3 there is illustrated a plan view of part of semiconductor (silicon) wafer 300 comprising an array of semiconductor dies 301 partially partitioned by milled channels 302 in accordance with a first preferred embodiment of the present invention. In FIG. 4 there is illustrated a cross sectional view through 4-4′ of the semiconductor (silicon) wafer 300 further showing the milled channels 302 partially partitioning the semiconductor dies 301. As shown, the milled channels 302 have opposing parallel vertical surfaces spaced between a horizontal surface.

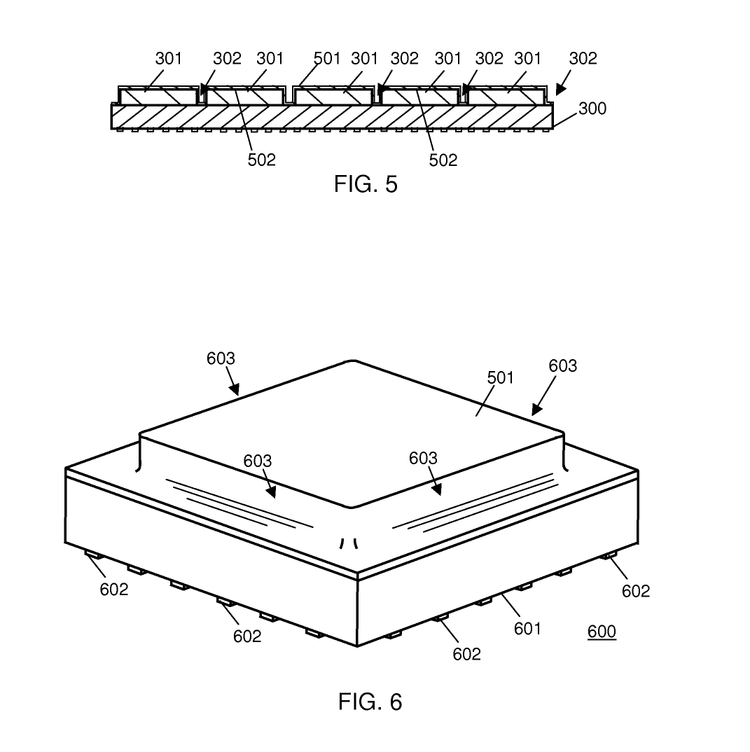

Referring to FIG. 5 there is illustrated a view of the silicon wafer 300 after an electrically conductive layer 501 has been deposited on a mounting surface 502 of the semiconductor dies 503 in accordance with a first preferred embodiment of the present invention. As shown, the electrically conductive layer 501 is deposited on the mounting surface 502 and also surfaces of the milled channels 302. The conductive layer 501 is deposited on the silicon wafer 300 by Atomic Layer Disposition (ALD), Chemical Vapour Deposition (CVD) or any other suitable depositing process that can form a continuos conductive layer (or film) covering one complete side of the silicon wafer 300.

Referring to FIG. 6 there is illustrated a perspective view of a singulated semiconductor die 600 removed from the array of semiconductor dies 301. The semiconductor die 600 has been singulated by a sawing (or milling) the silicon wafer 300 between the channels 302 as will be apparent to a person skilled in the art. The semiconductor die 600 has an interface surface 601 with associated interface electrodes 602 protruding from the interface surface 601. As shown, the electrically conductive layer 501 is deposited on the mounting surface 502 and also surfaces of recesses 603 that are formed from part of the milled channels 302.

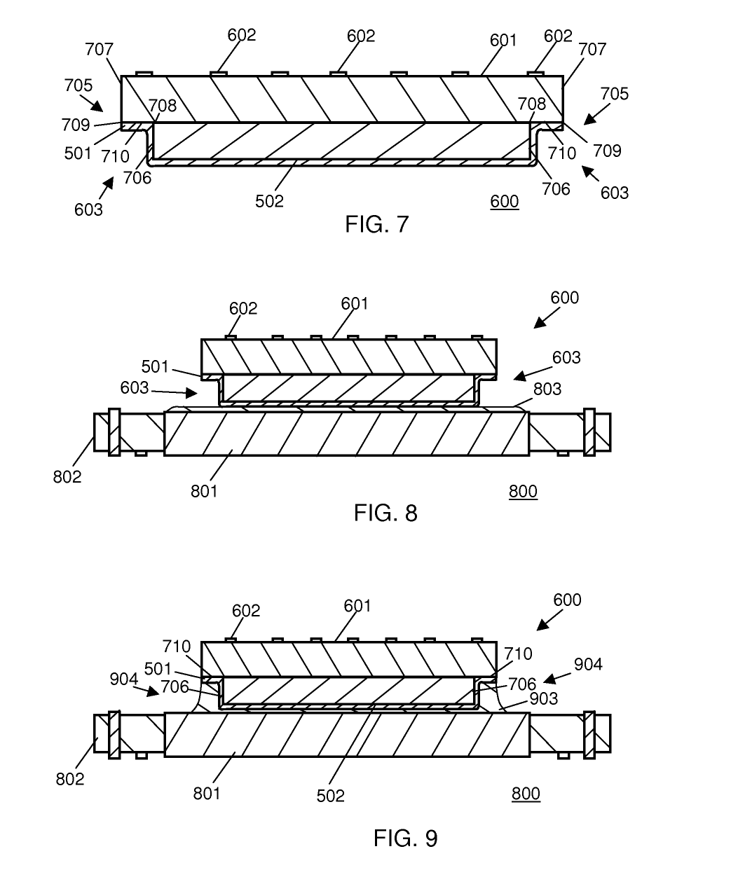

Referring to FIG. 7 there is illustrated an inverted cross sectional view of the singulated semiconductor die 600 in accordance with the first preferred embodiment of the present invention. More specifically, the semiconductor die 600 has four side regions 705 between the interface surface 601 and mounting surface 502 and the electrically conductive layer 501 is deposited on the mounting surface 502 and extends onto all four of the side regions 705. As illustrated, each of the side regions 705 comprises a first upright surface 706 and a second upright surface 707 partitioned from the a first upright surface 706 by corners 708, 709. The first upright surface 706, of each side region 705, is adjacent the mounting surface 502 and the second upright surface 507, of each side region 705, is adjacent the interface surface 601. Furthermore, the electrically conductive layer 501 is a continuous layer completely covering the first upright surface 706 and the mounting surface 502 but it does not cover the second upright surface 707.

Each upright surface 706 is part of (formed from) one of the recesses 603 in the side regions 705 and each of the recesses 603 forms a tertiary surface 710 between the first upright surface 706 and second upright surface 707. The first upright surface 706 and second upright surface 707 are parallel to each other and normal to the mounting surface 502, whereas the tertiary surface 710 is parallel to the mounting surface 502. Also, in this embodiment the electrically conductive layer 501 completely covers the tertiary surface 710.

FIG. 8 shows a partially assembly 800 of a semiconductor device. The assembly 800 includes the singulated semiconductor die 600 placed on a flag 801 of a substrate 802 in accordance with the first preferred embodiment of the present invention. More specifically, the semiconductor die 600 is placed on a solder paste compound 803 covering the flag 801.

Referring to FIG. 9, a view of the partial assembly 800 with a solder alloy 903 joining the semiconductor die 600 to the flag 801 in accordance with the first preferred embodiment of the present invention is shown. The solder alloy 903 is the solder paste compound 803 that has been heated (re-flowed) to form a joint 904. Thus, the solder alloy 903 joins the semiconductor die 600 to the flag 801. The solder alloy 903 is disposed between the flag 801 and the electrically conductive layer 501 and provides the joint 904 between the flag 801 and both the mounting surface 502 and the side regions 705. In this embodiment, the solder alloy 903 fills the recesses 603 so that the solder alloy 903 is joined to the flag 801 and the electrically conductive layer at the tertiary surface 710, first upright surface 706 and mounting surface 502.

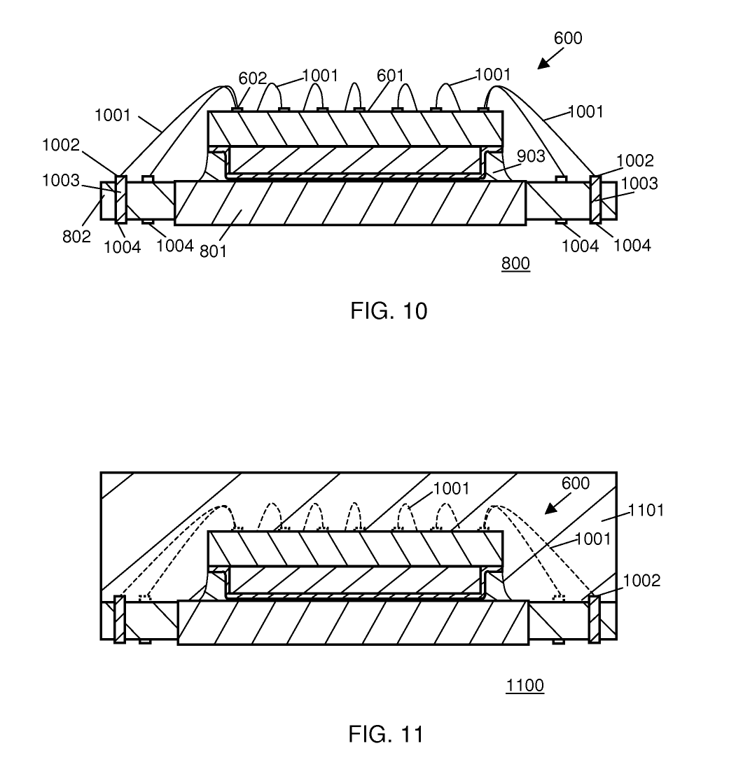

FIG. 10 shows the partial assembly 800 with electrical conductors in the form of wire bonds 1001 coupling the interface electrodes 602 of the semiconductor die 600 to respective external connector pads 1002 in accordance with the first preferred embodiment of the present invention. The external connector pads 1002 have a conductive path 1003 extending through the substrate 802 to mounting pads 1004 as will be apparent to a person skilled in the art. In this embodiment each external connector pad 1002, conductive path 1003 and mounting pad 1004 is formed from a metal pin, however, other embodiments are possible such as ball grid array mounting pads, electrically coupled through vias to the external connector pads 1002.

Referring to FIG. 11, a cross-sectional view of a semiconductor device 1100 in accordance with the first preferred embodiment of the present invention. The semiconductor device 1100 is the partial assembly 800 of FIG. 10 with an encapsulating material 1101 covering the semiconductor die 600, wire bonds 1001 and the external connector pads 1002. The encapsulating material 1101 in this embodiment is a molded plastics material and provides mechanical protection to the semiconductor die 600 and wire bonds 1001 and also provide a seal against moisture and dust.

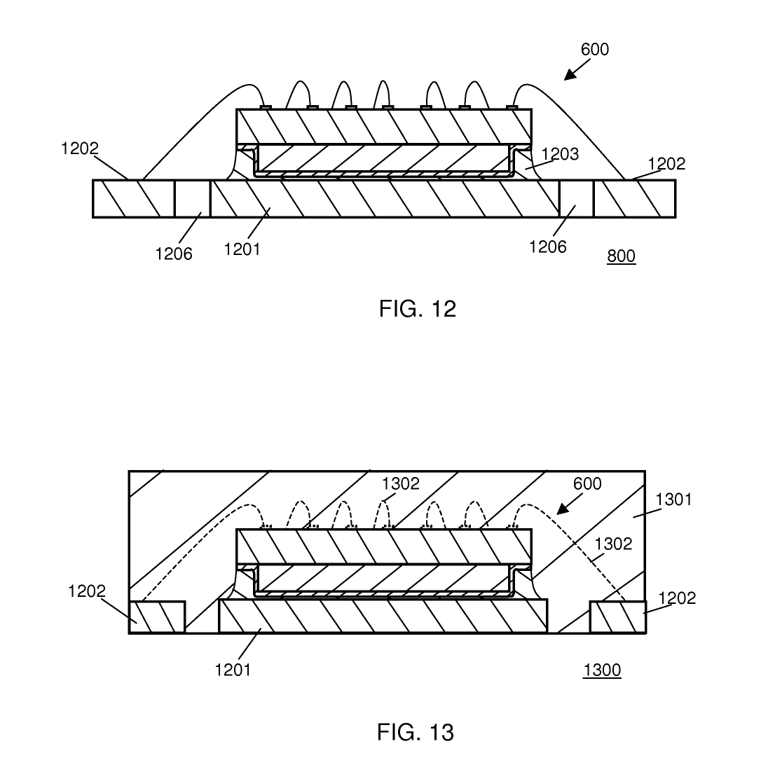

In FIG. 12 there is illustrated a cross sectional view of a partial assembly 1200 of a semiconductor device including the singulated semiconductor die of 600 joined by a solder alloy 1203 to a lead frame flag 1204 in accordance with a second preferred embodiment of the present invention. The lead frame flag is part of a lead frame that has tie-bars 1206 extending from the flag 1204 to support the external connector pads 1202 as will be apparent to a person skilled in the art.

FIG. 13 is a cross-sectional view a semiconductor device 1300 in accordance with the second preferred embodiment of the present invention. The semiconductor device 1300 is the partial assembly 1200 with an encapsulating material 1301 covering the semiconductor die 600, wire bonds 1302 and the external connector pads 1202. The encapsulating material 1101 in this embodiment is a molded plastics material and provides mechanical protection dust to the semiconductor die 600 and wire bonds 1302 and also provide a seal against moisture and dust. All other features and characteristics of the semiconductor device 1300 are the same as the semiconductor device 1100.

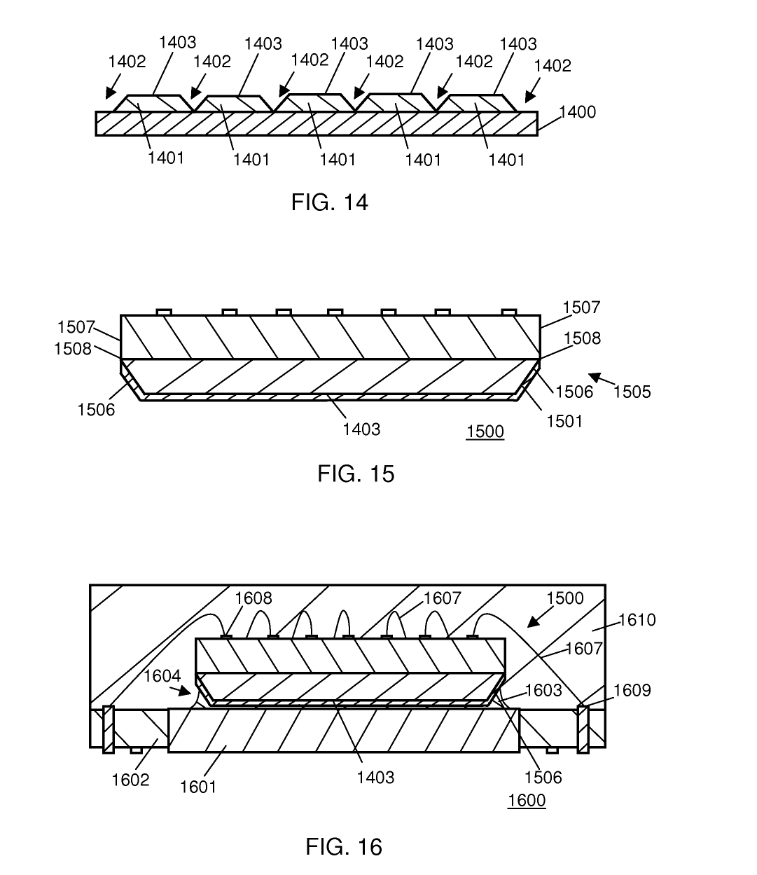

In FIG. 14 there illustrated a cross sectional view of part of silicon wafer 1400 comprising an array of semiconductor dies 1401 partially partitioned by milled channels 1402 in accordance with a third preferred embodiment of the present invention. As shown, the milled channels 1402 have opposing tapered surfaces at an angle to a mounting surface 1403 of each the dies in the array of semiconductor dies 1401.

Referring to FIG. 15, a cross-sectional view of a singulated semiconductor die 1500 in accordance with the third preferred embodiment of the present invention is shown. An electrically conductive layer 1501 has been deposited on the mounting surface 1403 and also surfaces of what remains of the milled channels 1402. The electrically conductive layer 1501 was deposited on the silicon wafer 1400, before singulation, by Atomic Layer Disposition (ALD, Chemical Vapour Deposition (CVD) or any other suitable depositing process. Furthermore, it will be apparent that the electrically conductive layer 1501 extends onto four side regions 1505 of the semiconductor die 1500. Also each of the side regions has a tapered first upright surface 1506 and a second upright surface 1507 partitioned from the tapered first upright surface 1506 by a corner 1508. Thus, as shown the electrically conductive layer 1500 is a continuos layer that completely covers the tapered first upright surface 1506 and the mounting surface 1403.

Referring to FIG. 16 there is illustrated a cross-sectional view a semiconductor device 1600 in accordance with the third preferred embodiment of the present invention. The semiconductor device 1600 includes the semiconductor die 1500 joined to a flag 1601 of a substrate 1602 by a solder alloy 1603. The solder alloy 1603 is the solder paste compound that has been heated (re-flowed) to form a joint 1604 between the flag 1601 and both the mounting surface 1403 and the tapered first upright surface 1506. More specifically, the solder alloy 1603 fills a space formed between the flag 1601 and the first tapered upright surface 1506.

Wire bonds 1607 couple interface electrodes 1608 of the semiconductor die 1500 to respective external connector pads 1609 of the substrate 1602. The semiconductor device 1600 has an encapsulating material 1610 that covers the semiconductor die 1500 and wired bonds 1607 to provide dust, water and mechanical protection to the semiconductor die 1500 and wire bonds 1607. All other features and characteristics of the semiconductor device 1600 are the same as the semiconductor device 1100.

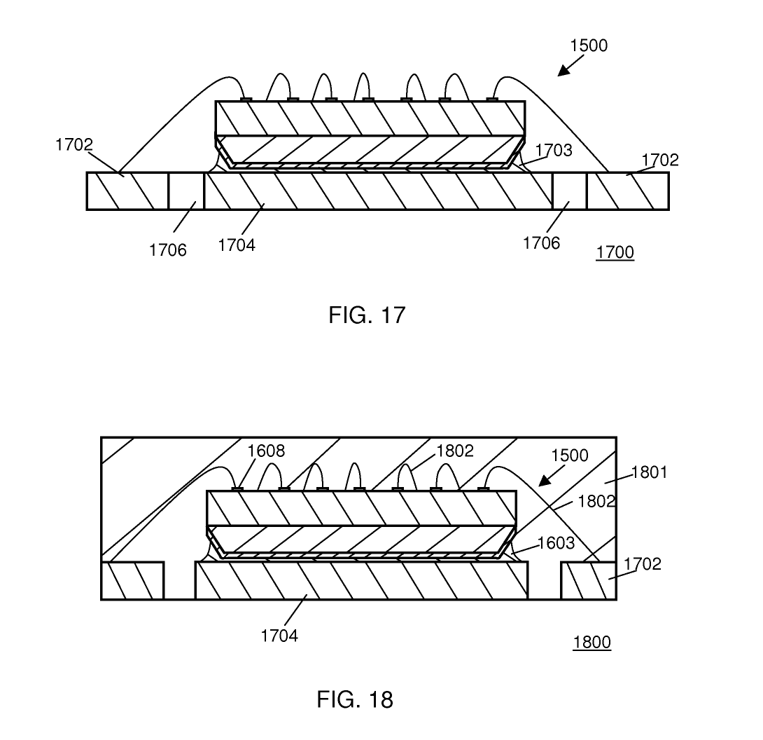

In FIG. 17 there is illustrated a cross-sectional view of a partial assembly 1700 of a semiconductor device including the singulated semiconductor die of 1500 joined by a solder alloy 1703 to a lead frame flag 1704 in accordance with a fourth preferred embodiment of the present invention. The lead frame-flag 1704 is part of a lead frame that has tie-bars 1706 extending from the flag 1704 to support the external connector pads 1702 as will be apparent to a person skilled in the art.

Referring to FIG. 8, there is illustrated a cross-sectional view a semiconductor device 1800 in accordance with the second preferred embodiment of the present invention. The semiconductor device 1800 is the partial assembly 1700 with an encapsulating material 1801 covering the semiconductor die 1500, wire bonds 1802 and the external connector pads 1702. The encapsulating material 1801 in this embodiment is a moulded plastics material and provides mechanical protection dust to the semiconductor die 1500 and wire bonds 1802 and also provide a seal against moisture and dust. All other features and characteristics of the semiconductor device 1800 are the same as the semiconductor device 1600.

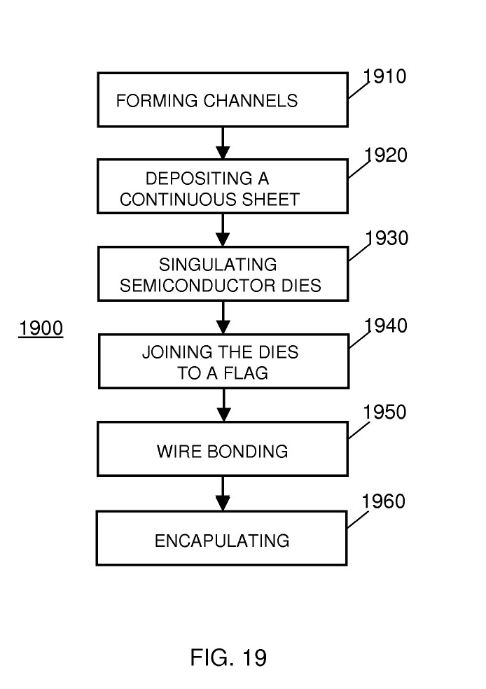

Referring to FIG. 19, a flow chart of a method 1900 for assembling a semiconductor device is shown. For ease of explanation the method 1900 will be described with reference to the semiconductor die 600 and semiconductor device 1100. However, it is to be understood that the method 1900 is not limited to the specific semiconductor die 600 or semiconductor device 1100.

The method 1900, at a forming block 1910, performs a process of forming channels 302 in a first side of a semiconductor wafer 300 to thereby partition semiconductor dies 301 in an array of such dies. At a depositing block 1920, the method 1900 performs a process of depositing a continuous sheet (electrically conductive layer 501) of electrically conductive material on the first side of the semiconductor wafer. As previously mentioned, the electrically conductive material is deposited on the silicon wafer 300 by Atomic Layer Disposition (ALD), Chemical Vapour Deposition (CVD) or any other suitable depositing process that can form a continuos conductive layer (or film) covering one complete first side of the silicon wafer 300.

At a singulating block 1930, there is performed a process of singulating the semiconductor dies 301 into individual dies 600. Each of these dies 600 includes an interface surface 601 with associated interface electrodes 602, and the interface surface is part of a second side of the semiconductor wafer that is opposite to the first side. A mounting surface 502 is formed from part of the first side of the semiconductor wafer 300 and there are side regions between the interface surface and mounting surface. The electrically conductive layer 501 covers the mounting surface 502 and part of each side region 705. At a joining block 1940, there is performed a process of joining the semiconductor die 600 to a flag 801 of a mount. The joining is effected by a solder alloy 903 disposed between the flag 801 and the electrically conductive layer 501 and the solder alloy 903 provides a joint between the flag 801, the mounting surface 502 and the side regions 705. When considering semiconductor die 600 the channels 302 form recesses 603 in the side regions 705 and the solder alloy 903 fills the recesses 603. In contrast, when considering the semiconductor die 1500, part of the channels 1402 form tapered upright surfaces 1506 in the side regions 1505 and the solder alloy 1603 fills spaces formed between the flag 1601 and the tapered upright surfaces 1506.

At a wire bonding block 1950 a process of wire bonding is then performed to wire bond the interface electrodes 602 to respective external connector pads 1002 of the mount. The semiconductor die 600 is then encapsulated at an encapsulating block 1960 to complete the manufacture of the semiconductor device 1100.

Advantageously, the present invention may allow for a reduction or elimination of voids in the solder compound near the periphery of the joint between the flag and semiconductor die. The joint integrity may be also visual inspected as a first instance or initial quality control check. Furthermore, the electrical conductivity of the joint may be improved resulting in less heat being generated by current flowing through the joint when functioning as a ground plane. It is further possible to potentially improve the mechanical strength of the joint because the solder alloy is also soldered to the side regions of the semiconductor die.

The description of the preferred embodiments of the present invention has been presented for purposes of illustration and description, but is not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiment disclosed, but covers modifications within the spirit and scope of the present invention as defined by the appended claims.

1. A semiconductor device, comprising:
a mount with a flag and external connector pads;
a semiconductor die having interface electrodes on an interface surface and an electrically conductive layer on a mounting surface that is opposite to the interface surface, wherein the electrically conductive layer extends onto at least one side region of the semiconductor die;
electrical conductors coupling the interface electrodes to respective ones of the external connector pads; and
a solder alloy joining the semiconductor die to the flag, wherein the solder alloy is disposed between the flag and the electrically conductive layer and provides a joint between the flag and both the mounting surface and the side region.

2. The semiconductor device of claim 1, wherein the electrically conductive layer extends onto two opposing side regions of the semiconductor die.

3. The semiconductor device of claim 1, wherein the electrically conductive layer extends onto four side regions of the semiconductor die.

4. The semiconductor device of claim 3, wherein each of the side regions comprises a first upright surface and a second upright surface partitioned from the first upright surface by at least one corner, the first upright surface of each side region being adjacent the mounting surface and the second upright surface of each side region being adjacent the interface surface, and wherein the electrically conductive layer covers the first upright surface and the mounting surface.

5. The semiconductor device of claim 4, wherein the electrically conductive layer is a continuos layer that completely covers the first upright surface and the mounting surface.

6. The semiconductor device of claim 4, wherein the second upright surface is normal the mounting surface.

7. The semiconductor device of claim 6, wherein the first upright surface is parallel to the second upright surface.

8. The semiconductor device of claim 7, wherein each first upright surface is part of a recess in the side region.

9. The semiconductor device of claim 8, wherein the recess forms a tertiary surface between the first upright surface and second upright surface, and wherein the electrically conductive layer completely covers the tertiary surface.

10. The semiconductor device of claim 9, wherein the solder alloy fills the recess so that the solder alloy is joined to the flag and the electrically conductive layer at tertiary surface, first upright surface and mounting surface.

11. The semiconductor device of claim 6, wherein the first upright surface is at an angle to the second upright surface.

12. The semiconductor device of claim 11, wherein the solder alloy fills a space formed between the flag and the first upright surface.

13. A semiconductor die, comprising:
an interface surface with associated interface electrodes;
a mounting surface that is opposite to the interface surface;
side regions between the interface surface and the mounting surface; and
an electrically conductive layer deposited on the mounting surface and at least one of the side regions.

14. The semiconductor die of claim 13, wherein the electrically conductive layer extends onto four side regions of the semiconductor die.

15. The semiconductor die of claim 14, wherein each of the side regions comprises a first upright surface and a second upright surface partitioned from the a first upright surface by at least one corner, the first upright surface of each side region being adjacent the mounting surface and second upright surface of each side region being adjacent the interface surface, and wherein the electrically conductive layer covers the first upright surface and the mounting surface.

16. The semiconductor die of claim 15, wherein the second upright surface is normal the mounting surface.

17. The semiconductor die of claim 15, wherein each first upright surface is part of a recess in the side region and the recess forms a tertiary surface between the first upright surface and second upright surface, and wherein the electrically conductive layer completely covers the tertiary surface.

18. A method for assembling a semiconductor device, comprising:
forming channels in a first side of a semiconductor wafer to thereby partition semiconductor dies formed in the wafer into an array of semiconductor dies;
depositing a continuous sheet of electrically conductive material on the first side of the semiconductor wafer, wherein the electrically conductive material forms a continuous film that completely covers the first side;
singulating the wafer into individual semiconductor dies, wherein each of the semiconductor dies includes:
an interface surface with associated interface electrodes, the interface surface being part of a second side of the semiconductor wafer that is opposite to the first side;
a mounting surface formed from part of the first side of the semiconductor wafer; and
side regions between the interface surface and mounting surface, wherein the electrically conductive layer covers the mounting surface and at least part of each side region;
joining the semiconductor die to a flag of a mount with a solder alloy, wherein the solder alloy provides a joint between the flag, the mounting surface and the side regions;
electrically connecting the interface electrodes to respective external connector pads of the mount with bond wires; and
encapsulating the semiconductor die.

19. The method of claim 18, wherein part of the channels form recesses in the side regions and the solder alloy fills the recesses.

20. The method of claim 18, wherein part of the channels form tapered upright surfaces in the side regions and the solder alloy fills spaces formed between the flag and the tapered upright surfaces.
